(19) United States
(12) Patent Application Publication
(10) Pub. No.: US 2008/0092944 A1
(43) Pub. Date: Apr. 24, 2008

(54) Semiconductor structure and process for forming ohmic connections to a semiconductor structure

(76) Inventor: Leonid Rubin, Burnaby (CA)

Correspondence Address: KNOBBE MARTENS OLSON & BEAR LLP, 2040 MAIN STREET, FOURTEENTH FLOOR, IRVINE, CA, 92614, US

(21) Appl. No.: 11/581,769

(22) Filed: Oct. 16, 2006

(51) Int. Cl. H01L 31/00

(52) U.S. Cl. 136/252

(57) ABSTRACT

A semiconductor apparatus is disclosed. The apparatus includes a first doped volume of semiconductor material, the first doped volume having a front surface and first and second adjacent regions. The first region has a first concentration of dopant and a first exposed area on the front surface. The second region has a second concentration of dopant and a second exposed area on the front surface, the second concentration being higher than the first concentration. The apparatus also includes a first external conductor and an alloy bonding the first external conductor to the second exposed area to ohmically connect the conductor to the second region.

### BACKGROUND OF THE INVENTION

1. Field of Invention

The present invention generally relates to semiconductor devices and more particularly to forming ohmic connections between external conductors and semiconductor devices.

2. Description of Related Art

Making ohmic contact to a semiconductor device typically involves deposition of a contact metal by screen printing, sputtering, evaporation, or chemical vapor deposition. The device is then generally annealed to cause the metal to at least partly diffuse into the semiconductor material to create an internal ohmic contact. Generally the process is time and energy consuming, complicated, and may be expensive to implement, particularly for large area semiconductor devices such as photovoltaic cells.

Crystalline silicon photovoltaic (PV) cells are generally produced from a wafer having a p/n junction. The p/n junction may be produced by diffusion of either phosphorus or boron into a front side of a p-type or n-type semiconductor substrate. A portion of the PV cell, between its front side and the p/n junction creates what is known as an emitter. Under illumination by light the PV cell generates electric current as a result of charge separation within the p/n junction area. This electric current is collected from the PV cell by front and back side metal contacts.

The metal contacts are typically provided through the use of screen printing technology, involving a partially electrically conductive paste, which typically contains silver and/or aluminum, which is screen printed onto front and back surfaces of the cell through a mask.

For the front side of the PV cell, the mask typically has openings through which the conductive paste contacts the semiconductor substrate surface. The front side mask is typically configured to produce a plurality of thin parallel line contacts and two or more thicker lines that are connected to, and extend generally perpendicular to the parallel line contacts. After spreading paste on the mask, the mask is removed and the wafer bearing the partially conductive paste is heated to dry the paste. The wafer is then “fired” in an oven and the paste enters a metallic phase, where at least part of it diffuses through the front surface of the solar cell and into the cell structure while a portion is left solidified on the front surface. The multiple thin parallel lines thus form thin parallel linear current collecting areas referred to as “fingers”, intersected by thicker perpendicular lines referred to as “bus bars”. The fingers collect the electrical current from the front side of the PV cell and transfer the current to the bus-bars.

Typically, the width and the height of each finger is approximately 120 microns and 10 microns respectively. While the fingers are sufficient to collect small electric currents from the PV cell, the bus-bars are required to collect a much greater current from the plurality of fingers and therefore have correspondingly larger cross section and width.

For the back surface of the PV cell a partially conductive paste containing aluminum is spread over the entire back surface of the cell except for a few small areas. The past is dried by heating (generally simultaneous with the heating of the front side paste). Then silver/aluminum paste is screen printed in certain areas that have not been printed with aluminum paste and the paste is dried by a further heating step. When the wafer is subjected to “firing” in the oven, part of the aluminum diffuses into the back surface of the PV cell which produces a highly doped p+ layer, or back surface field (BSF). The aluminum also alloys with the silver/aluminum paste and forms silver/aluminum pads. The back surface field collects electrical current from rear side of PV cell and conducts it to the silver/aluminum pads, which act as terminals from the PV cell.

The area that is occupied by the fingers and bus bars on the front side of the solar cell is known as the shading area because solar radiation is prevented from reaching the solar cell surface in this area. This shading area decreases solar cell conversion efficiency. Modern solar cell shading occupies 6-10% of the available solar cell surface area. The presence of metal contacts on the front side and the silver/aluminum pads on the back side results in a decrease of voltage generated by the PV cell in proportion to the metalized area. Furthermore, diffusion of the contact metal into the front surface of the PV cell has a detrimental effect on charge recombination.

Conventional metallization techniques may also introduce bowing of the solar cell due to the difference in thermal expansion coefficients between silicon material and silver/aluminum pastes. Bowing may be very pronounced on thin solar cells, which may be less than 180 micron thick, making such cells fragile thus reducing production yield.

U.S. Pat. No. 6,982,218 entitled Method of Producing a Semiconductor-Metal Contact through a Dielectric Layer to Preu et al., describes a method of electrically contacting a semiconductor layer coated with at least one dielectric layer. The metal layer is applied over the dielectric layer and is temporarily locally heated in linear or dotted patterns by means of a controlled source of radiation. The heating causes a localized molten mixture of the metal layer, the dielectric layer, and the semiconductor layer. The dielectric layer and semiconductor layer are located directly underneath the metal layer and upon solidification, provide an electric contact between the semiconductor layer and the metal layer. The Dielectric layer is very thin (less than 1 micron and preferably in the range from 10 nanometers to 500 nanometers) and metal layer is preferably aluminum of approximately 2 micron thickness. The thin metal layer generally does not produce the bowing effect, even when used with very thin silicon wafers. This method may be attractive for mass production of efficient PV cells due to the efficient passivation of their back side after the dielectric layer is applied according to the proposed method. At the same time the need to use an additional coating of aluminum with an intermediate metallic layer in order to arrange reliable electrical contacting with electrical leads still appears to be a problem.

International Application WO 2004/021455 entitled “Electrode for Photovoltaic Cells, Photovoltaic Cell and Photovoltaic Module”, to Rubin et al. describes a current collecting electrode employing a low melting point alloy that is able to establish low resistive contact with a conductive antireflection coating that is applied on the front side of a PV cell and with back side screen printed aluminum metallization. This technology eliminates the need for conventional screen printing metallization on the front side of the solar cell, but still employs an intermediate conductive layer between current collecting electrode and PV cell front surface comprising doped area.

With thin film photovoltaic cells it is impossible to use technology that is conventional for crystalline silicon. In this case PV cells in the form of a thin film are deposited on conductive material by chemical vapor deposition. The thin film may be a transparent conductive material such as Tin or Indium Oxide or a metallic foil. Interconnecting PV cells formed in this way may be achieved using special conductive adhesive pastes. These pastes are applied on metallic conductors, for example wires or tabs allowing them to be fixed to the surface of a PV cell by the properties of the paste. Unfortunately conductive pastes are expensive due to consumption of silver and have substantial electrical resistivity that is at least 10 times higher than copper wire.

It is known that PV solar cells experience substantial losses in the emitter region. Therefore in order to increase conversion efficiency of solar cells that employ conventional screen printed metallization it is often recommended to optimize emitter parameters in such a way that in the light illuminated areas doping concentration levels should be as low as possible to provide for maximum photon collection and charge separation whereas doping concentrations and diffusion depths in the areas under current collecting metallic contacts should be substantially higher to provide low resistance electric contact with screen printed metallic patterns without shunting the p/n junction. In other words it is desirable to build solar cells with a selective emitter that contains areas with different dopant concentration and different depths of diffusion. Although the use of a selective emitter has proved to be effective in improving PV solar cell efficiency, implementation of a selective emitter in practice, is quite complicated.

U.S. Pat. No. 5,871,591 entitled Silicon Solar Cells made by a Self-Aligned, Selective-Emitter, Plasma-Etchback Process, to Ruby et al describes a process for forming and passivating a selective emitter. The process uses a plasma etch of the heavily doped emitter to improve its performance. The screen printed metallic patterns, so called grids of the solar cell, are used to mask the plasma etch so that only the emitter in the region between the grids is etched, while the region beneath the grids remains heavily doped to secure low contact resistance with screen printed metallic grids. This process is potentially low-cost because it does not require precision alignment between heavily doped regions and screen printed patterns. After the emitter is etched, a silicon nitride is deposited by plasma-enhanced chemical vapor deposition, thereby creating an antireflection coating. The solar cell is then annealed in a forming gas. While this method allows fabricating a selective emitter and increased solar cell efficiency, it has a disadvantage in that selective emitter formation happens only after screen printed metallic patterns have been formed on the solar cell. Therefore the patent is still based on conventional screen printing metallization techniques.

U.S. Pat. No. 6,091,021 entitled “Silicon Solar Cells made by a Self-Aligned, Selective-Emitter, Plasma-Etchback Process” to Ruby et al describes photovoltaic cells and a method for making them wherein metalized grids of the cells are used to mask portions of cell emitter regions to allow selective etching of phosphorous-doped emitter regions. This self-aligned selective etching allows for enhanced blue response (versus cells with uniform heavy doping of the emitter) while preserving heavier doping in the region beneath the gridlines needed for low contact resistance. This may replace expensive and difficult alignment methodologies used to obtain selectively etched emitters, and may be easily integrated with existing plasma processing methods and techniques. However, the proposed method requires that selective emitter formation be done only after screen printed metallization has been applied on the solar cell. Again therefore, conventional screen printing metallization is required.

U.S. Pat. Nos. 6,552,414 and 6,825,104 both entitled “Semiconductor Device with Selectively Diffused Regions” to Horzel et al. describe a PV cell having two selectively diffused regions with different doping levels. A first screen printing process is used to deposit a paste containing dopant on diffusion regions of a substrate to produce highly doped emitter regions. A second screen printing process is used to deposit a metallization pattern for connecting to the highly doped emitter regions. The second screen printing process requires precise alignment to ensure that connection is made to the highly doped emitter regions.

There remains a need for better methods and apparatus for making ohmic contact to semiconductor structures without detraction from cell efficiency, without risk of bowing, without risk of excessive breakage, without consumption of metallic pastes and without the complications that accompany screen printing. In particular there remains a need for improved methods for making contact to photovoltaic semiconductor structures.

### SUMMARY OF THE INVENTION

In accordance with one aspect of the invention there is provided a semiconductor apparatus. The apparatus includes a first doped volume of semiconductor material, the first doped volume having a front surface and first and second adjacent regions. The first region has a first concentration of dopant and a first exposed area on the front surface. The second region has a second concentration of dopant and a second exposed area on the front surface, the second concentration being higher than the first concentration. The apparatus also includes a first external conductor and an alloy bonding the first external conductor to the second exposed area to ohmically connect the conductor to the second region.

The first region may have a sheet resistance in the range of between about 80 ohms/sq to about 150 ohms/sq.

The second region may have a sheet resistance in the range of between about 0.5 ohms/sq to about 40 ohms/sq.

The second region may include a plurality of separate second regions, each of the separate second regions generally having a concentration of dopant approximately equal to the second concentration and each of the separate second regions having a respective second exposed surface.

The first external conductor may be bonded to the second exposed areas of at least two of the plurality of second regions.

The regions of the plurality of second regions may be distributed across the front surface.

The regions of the plurality of second regions may be distributed across the front surface in parallel spaced apart rows.

The regions in a first parallel spaced apart row may be staggered relative to the regions in a second adjacent parallel row.

The first external conductor may include a plurality of conductors, each of the plurality of conductors being bonded to a plurality of the second exposed areas of respective the second regions in one of the plurality of parallel rows.

The first external conductor may include at least one of silver, copper, and alloys thereof.

The first external conductor may include a wire having a diameter of between about 30 microns and about 200 microns.

The first external conductor may include at least a portion having a cross sectional shape that is generally circular or generally rectangular or generally triangular.

A portion of the first external conductor may be adhered to a polymeric film and the polymeric film is adhered to the front surface.

The polymeric film may include polyester.

The polymeric film may have a thickness of between about 6 microns and about 100 microns.

The apparatus may include an adhesive between the polymeric film and the front surface, the adhesive being operable to adhere the polymeric film to the front surface.

The adhesive may have thermoplastic properties.

The adhesive may become fluid when subjected to a temperature in the range of between about 60 degrees Celsius and about 170 degrees Celsius.

The adhesive may become fluid when subjected to a temperature in the range of between about 80 degrees Celsius and about 150 degrees Celsius.

The adhesive may have a thickness of between about 20 microns and about 200 microns.

The alloy may include a composition including at least two of: Ag, Bi, Cd, Ga, In, Pb, Sb, Sn, and Zn.

The alloy may include In, Sn, and Ag in a proportion of about 47% In, about 51% Sn, and about 2% Ag.

The alloy may include In and Sn in a proportion of about 48% In and about 52% Sn.

The alloy may have a thickness of between about 1 micron and about 5 microns.

The alloy may have a melting temperature of between about 30 degrees Celsius and about 200 degrees Celsius.

The alloy may have a melting temperature of between about 60 degrees Celsius and about 150 degrees Celsius.

The apparatus may include a layer of dielectric material between the alloy and the second exposed area, the layer of dielectric material being operable to passivate the second exposed area and being sufficiently thin to permit charge carriers to tunnel through the layer of dielectric material between the second exposed area and the alloy.

The dielectric material may include silicon nitride or silicon dioxide.

The layer of dielectric material may have a thickness of less than about 2 nanometers.

The apparatus may include interconnecting regions extending between at least some of the second regions, the interconnecting regions having a dopant concentration approximately equal to the second dopant concentration, the interconnecting regions being operable to interconnect the second regions within the first doped volume.

The first doped volume may have a first dopant polarity and the apparatus may further include a second doped volume of semiconductor material adjacent to the first doped volume and having a opposite dopant polarity to the first dopant polarity, the first and second volumes of semiconductor material forming a p/n junction therebetween.

The p/n junction may be operably configured to separate charge carriers in response to irradiation of the apparatus by light.

The apparatus may include an antireflective layer on the front surface, the antireflective layer having an opening aligned with the second exposed area, the antireflective layer being operably configured to facilitate coupling of the light into the semiconductor apparatus.

The apparatus may include a passivation layer on the front surface, the passivation layer having an opening aligned with the second exposed area.

The second doped volume may include a back surface and third and fourth regions, the third region having a third concentration of dopant and a third exposed area on the back surface, the fourth region having a fourth concentration of dopant and a fourth exposed area on the back surface, the fourth concentration being higher than the third concentration.

The third region may have a sheet resistance in the range of between about 20 ohms/sq to about 60 ohms/sq.

The fourth region may have a sheet resistance in the range of between about 0.1 ohms/sq to about 20 ohms/sq.

The apparatus may include a second external conductor and an alloy on the second external conductor, the alloy bonding the second conductor to the fourth exposed area to ohmically connect the second conductor to the fourth region.

The fourth region may include a plurality of separate fourth regions, each of the separate fourth regions generally having a concentration of dopant approximately equal to the fourth concentration and each of the fourth regions having a corresponding fourth exposed surface.

In accordance with another aspect of the invention there is provided a semiconductor apparatus. The apparatus includes a first doped volume of semiconductor material, the first doped volume having a front surface and first and second adjacent regions, the first region having a first concentration of dopant and a first exposed area on the front surface, the second region having a second concentration of dopant and a second exposed area on the front surface, the second concentration being higher than the first concentration. The apparatus also includes a first external conductor and first provisions for bonding the first external conductor to the second exposed area to ohmically connect the first conductor to the second region.

The first provisions for bonding may include an alloy.

The apparatus may include first provisions for holding the first external conductor.

The first provisions for holding may include a first polymeric film and a first adhesive securing the first conductor to the first polymeric film.

The first adhesive may be operably configured to secure the first polymeric film to the front surface.

The apparatus may include provisions for passivating the second exposed area.

The provisions for passivating may include a layer of dielectric material between the second exposed area and the provisions for bonding.

The second regions may include a plurality of second regions, each having a respective second exposed surface and the apparatus may further include provisions for interconnecting at least some of the second regions together.

The provisions for interconnecting may include provisions for interconnecting regions having a dopant concentration approximately equal to the second dopant concentration.

The first doped volume may have a first dopant polarity and the apparatus may further include a second doped volume of semiconductor material adjacent to the first doped volume and having a second dopant polarity opposite to the first dopant polarity, the first and second volumes of semiconductor material forming a p/n junction therebetween.

The second doped volume may include a back surface and third and fourth regions, the third region having a third concentration of dopant and a third exposed area on the back surface, the fourth region having a fourth concentration of dopant and a fourth exposed area on the back surface, the fourth concentration being higher than the third concentration.

The apparatus may include a second external conductor, and second provisions for bonding the second conductor to the fourth exposed area to ohmically connect the second conductor to the fourth region.

The second provisions for bonding may include an alloy.

The apparatus may include second provisions for holding the second external conductor.

The second provisions for holding may include a second polymeric film and a second adhesive securing the second conductor to the second polymeric film.

The second adhesive may be operably configured to secure the second polymeric film to the back surface.

In accordance with another aspect of the invention there is provided a process for making an electrical connection to a semiconductor structure including a first doped volume of semiconductor material, the first doped volume having a front surface and first and second adjacent regions, the first region having a first concentration of dopant and a first exposed area on the front surface, the second region having a second concentration of dopant and a second exposed area on the front surface, the second concentration being higher than the first concentration. The process involves bonding a first external conductor to the second exposed area to ohmically connect the first conductor to the second region.

Bonding may involve melting and pressing an alloy between the first external conductor and the second exposed area.

The process may involve holding the first external conductor.

Holding may involve adhesively securing the first conductor to a first polymeric film.

The process may involve securing the first polymeric film to the front surface.

The process may involve passivating the second exposed area.

Passivating may involve forming a layer of dielectric material on the first surface, prior to bonding.

The process may involve interconnecting together at least some of a plurality of separate second regions.

Interconnecting may involve doping the semiconductor structure to form interconnecting regions between the separate second regions, the interconnecting regions having a dopant concentration approximately equal to the second dopant concentration.

The first doped volume may have a first dopant polarity and the semiconductor structure may further include a second doped volume of semiconductor material adjacent to the first doped volume and having a opposite dopant polarity to the first dopant polarity, the first and second volumes of semiconductor material forming a p/n junction therebetween, the second doped volume including a back surface and third and fourth regions, the third region having a third concentration of dopant and a third exposed area on the back surface, the fourth region having a fourth concentration of dopant and a fourth exposed area on the back surface, the fourth concentration being higher than the third concentration, and the process may involve bonding a second external conductor to the fourth exposed area to ohmically connect the second conductor to the fourth region.

Bonding the second conductor may involve melting and pressing an alloy between the second conductor and the fourth exposed area.

The process may involve holding the second external conductor.

Holding the second external conductor may involve adhesively securing the second external conductor to a second polymeric film.

The process may involve adhesively securing the second polymeric film to the back surface of the semiconductor structure.

In accordance with another aspect of the invention, in a semiconductor structure having a first doped volume of semiconductor material, the first doped volume having a front surface and first and second adjacent regions, the first region having a first concentration of dopant and a first exposed area on the front surface, the second region having a second concentration of dopant and a second exposed area on the front surface, the second concentration being higher than the first concentration there is provided a process for forming electrical connection to the semiconductor structure, The process involves cleaning the second exposed area on the front surface of the semiconductor material, pressing a first external conductor coated with an alloy into contact with the second exposed area, while heating the alloy to a temperature sufficient to at least partially melt the alloy, and maintaining the pressing while cooling the alloy to cause the alloy to solidify, thereby bonding the first conductor to the second exposed area such that the first conductor is in ohmic contact with the second region.

Cleaning may involve etching the front surface to remove oxides from the second exposed area.

Pressing may involve pressing to a pressure of between about 0.1 bar and about 1 bar.

Heating may involve heating the structure to cause the alloy to be heated to a temperature of between about 30 degrees Celsius and about 200 degrees Celsius.

Heating may involve heating the structure to cause the alloy to be heated to a temperature of between about 60 degrees Celsius and about 150 degrees Celsius.

The conductor may be adhered to a polymeric film and pressing may involve pressing the conductor into contact with the second exposed area.

Pressing may further involve adhering the polymeric film to the front surface.

The semiconductor structure may include an antireflective layer on the first exposed surfaces and pressing may involve adhering the polymeric film to at least a portion of the antireflective layer.

The process may involve forming a passivation layer on the second exposed area and pressing may involve pressing the first conductor such that the alloy bonds the conductor to the second region through the passivation layer.

Forming the passivation layer may involve forming a layer of dielectric material on the second exposed area.

Forming the layer of dielectric material may involve forming a layer of silicon nitride or silicon dioxide on the second exposed area.

Forming the layer of dielectric material may involve forming a layer of dielectric material such that the layer has a thickness of about 2 nanometers or less.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is a schematic cross sectional view of a semiconductor apparatus in accordance with a first embodiment of the invention;

FIG. 2 is a perspective view of the semiconductor structure shown in FIG. 1;

FIG. 3 is a plan view of the semiconductor structure shown in FIG. 1 in accordance with an alternative embodiment of the invention;

FIG. 4 is a plan view of the semiconductor structure shown in FIG. 1 in accordance with an alternative embodiment of the invention;

FIG. 5 is a plan view of the semiconductor structure shown in FIG. 1 in accordance with an alternative embodiment of the invention;

FIG. 6 is a schematic cross sectional view of a semiconductor structure in accordance with a second embodiment of the invention;

FIG. 7 is a schematic cross sectional view of a semiconductor apparatus in accordance with an embodiment of the invention including the semiconductor structure shown in FIG. 6;

FIG. 8 is a perspective view of the semiconductor apparatus shown in FIG. 7, showing electrodes being connected to the semiconductor structure; and

FIGS. 9-15 are a series of schematic cross-sectional views illustrating a process for producing the semiconductor structure shown in FIG. 7, in accordance with an embodiment of the invention.

### DETAILED DESCRIPTION

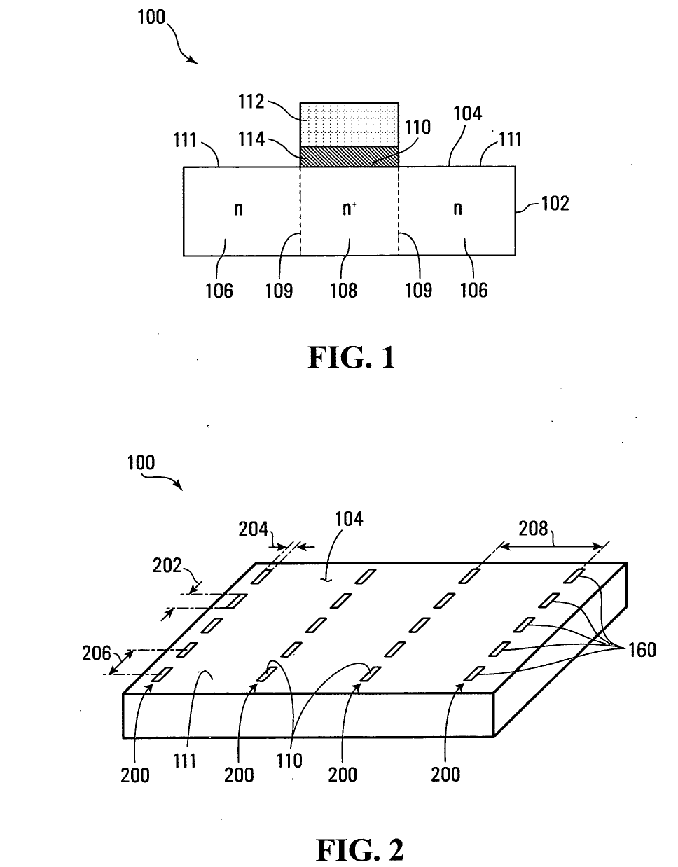

Referring to FIG. 1, a semiconductor apparatus in accordance with a first embodiment of the invention is shown generally at 100. The semiconductor apparatus 100 includes a first doped volume 102 of semiconductor material, having a front surface 104. The first doped volume 102 includes a first region 106 having a first concentration of dopant and a first exposed area 111 on the front surface 104. The first concentration of dopant causes the first region 106 to have a first polarity type such as n-type, for example. The first doped volume 102 also includes a second region 108 adjacent the first region 106. The second region 108 has a second concentration of the same dopant used to dope the first region 106 and has a second exposed area 110 on the front surface 104. The concentration of dopant in the second region 108 is higher than the concentration of dopant in the first region 106 and causes the second region 108 to have the same polarity type as the first region. Where n-type dopants are used, to distinguish between these two regions the first region may be designated as an n region and the second region may be designated an n+ region.

In one embodiment the first doped volume 102 includes n-type dopant elements in a concentration sufficient to cause the first region 106 to have a sheet resistance of between about 80 ohms/sq to about 150 ohms/sq. The concentration of dopant in the second region 108 is selected to cause the second region to have a sheet resistance of between about 0.5 ohms/sq and about 40 ohms/sq.

In the embodiment shown the second region 108 extends through the first region 106, however in other embodiments (not shown) the second region 108 may extend only partway through the first region 106, or may extend beyond the first region into an adjacent doped volume of semiconductor material, as shown later herein. A boundary 109 exists between the first region 106 and the second region 108. This boundary 109 may be referred to as an isotype junction to indicate that the junction is between semiconductor materials having a common polarity type.

The semiconductor apparatus 100 further includes a first external conductor 112. The first external conductor 112 is bonded to the second exposed area 110 by an alloy 114. The alloy 114 facilitates ohmic connection between the first external conductor 112 and the second region 108.

In one embodiment the alloy 114 includes an alloy of indium (In), tin (Sn), and silver (Ag) in a proportion of about 47% In, about 51% Sn, and about 2% Ag, and has a thickness of between about 1 micron and about 5 microns. In another embodiment the alloy 114 includes an alloy of indium (In) and tin (Sn) in a proportion of about 48% In to about 52% Sn. In other embodiments the alloy 114 may include two or more of the following metals: silver (Ag), bismuth (Bi), cadmium (Cd), gallium (Ga), indium (In), lead (Pb), antimony (Sb), tin (Sn), and zinc (Zn), for example. In general, the metals included in the alloy 114 are selected to cause the alloy to have a melting temperature of between about 30 degrees Celsius and about 200 degrees Celsius, and more particularly, a melting temperature of between about 60 degrees Celsius and about 150 degrees Celsius.

The first external conductor 112, in this embodiment, includes a wire of rectangular cross section, but in other embodiments the conductor may have a generally circular or triangular cross section. The first external conductor 112 may include a metal wire such as silver or copper, or alloys thereof, for example, and the conductor may have a diameter of between about 30 microns and 300 microns.

Referring to FIG. 2, in one embodiment, the second exposed areas 110 of the plurality of separate second regions 108 may be arranged in a plurality of parallel rows 160 and columns 200, each row and column including a plurality of generally rectangular second exposed areas 110. Each of the second exposed areas 110 has a second region 108 (shown in FIG. 2) underlying the second exposed areas. The second exposed areas 110 are surrounded by the first exposed area 111, and the first region 106 underlies the first exposed areas.

The second exposed areas 110 may have a generally rectangular shape and may have a length 202 in the range of approximately 1 millimetre to approximately 10 millimetres, and a width 204 in the range of between about 50 microns to about 150 microns. The columns 200 may be parallel and spaced apart such that a spacing distance 206 between adjacent second exposed areas 110 in the same column is about 1 millimetre to about 3 millimetres and such that a distance 208 between adjacent rows 160 is between about 1 millimetre and about 10 millimetres.

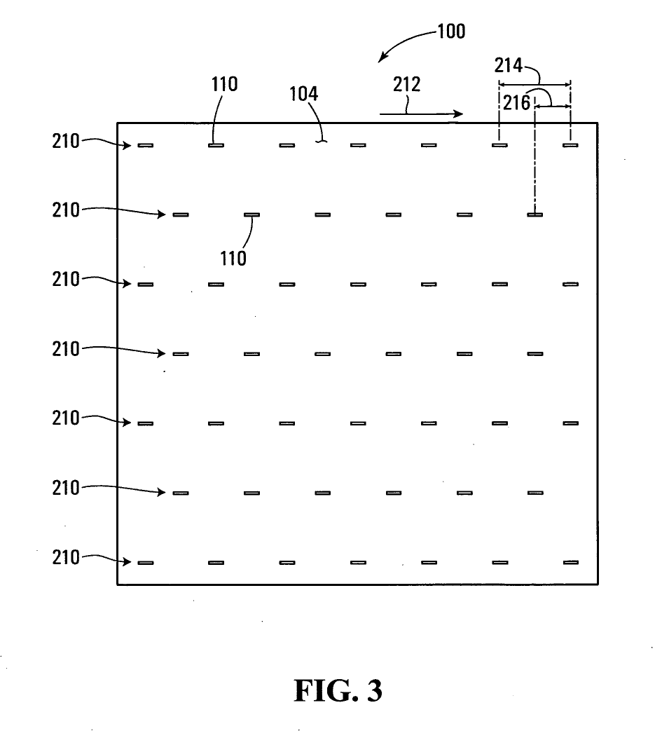

Referring to FIG. 3, in an alternative embodiment the second exposed areas 110 on the front surface 104 may be arranged in a plurality of parallel spaced apart rows 210, and the second exposed areas in adjacent rows may be staggered in a direction shown by arrow 212. In the embodiment shown, a distance 214 between the second exposed areas 110 in the same row is about 1 millimetre to about 3 millimetres, and the second exposed areas in adjacent rows are staggered by a distance 216, which in this embodiment is approximately half of the distance 214.

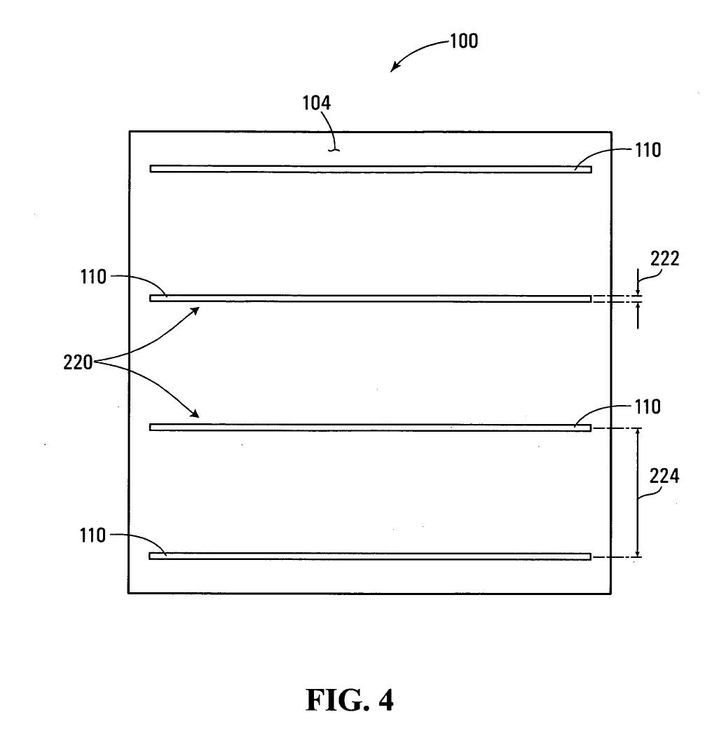

Referring to FIG. 4, in another embodiment the second exposed areas 110 on the front surface 104 (and the underlying second regions 108) may be elongated to form single parallel spaced apart elongate areas 220 extending across the front surface of the semiconductor apparatus 100. The elongate areas 220 may have a width 222 in the range of about 50 microns to about 150 microns and a distance 224 between adjacent parallel lines may be in the range of about 1 millimetre to about 5 millimetres.

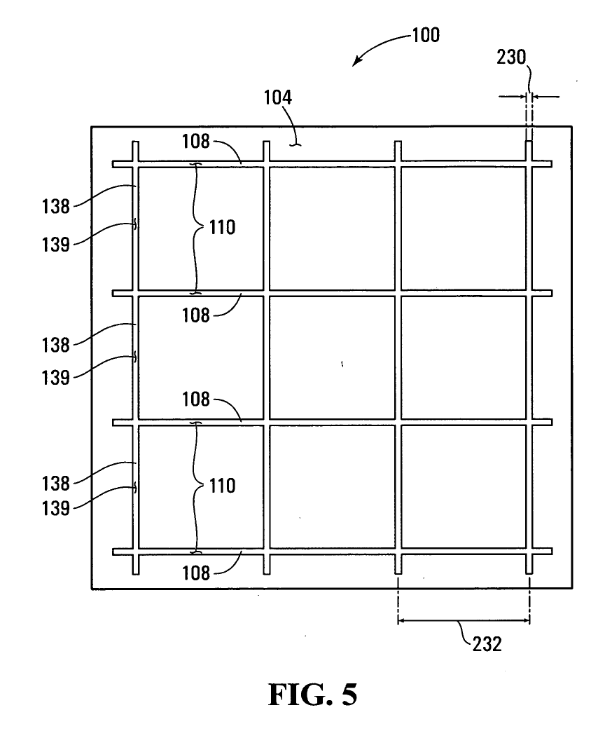

Referring to FIG. 5, in yet another embodiment the semiconductor apparatus 100 shown in FIG. 5 may be further provided with transverse interconnecting regions 138 extending between the second regions 108. The interconnecting regions 138 have a dopant concentration that is approximately equal to the second concentration of dopant in the second regions 108 and each interconnecting region 138 has an exposed area 139 on the front surface 104, to define a square mesh pattern across the front surface 104. In one embodiment the interconnecting regions 138 have a width of between about 50 microns and about 150 microns and are separated by a distance of between about 1 and about 5 millimeters.

### Semiconductor Structure

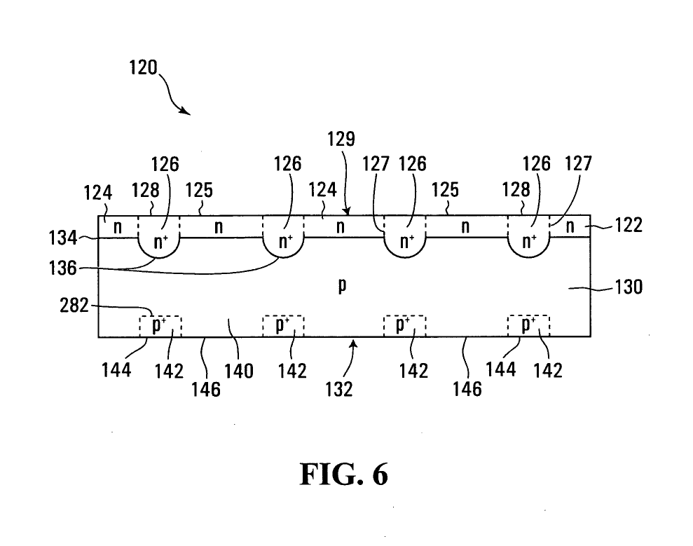

Referring to FIG. 6, a semiconductor structure in accordance with a second embodiment of the invention is shown generally at 120. The semiconductor structure 120 includes a first doped volume 122 having a front surface 129. The first doped volume 122 includes a first region 124 having a first concentration of dopant such as phosphorous that causes it to have an n-type polarity. The first region 124 also has a first exposed area 125 on the front surface 129. The first doped volume 122 further includes a plurality of separate second regions 126 having a second concentration of dopant of the same polarity as the first region 124 (in this case a phosphorous dopant). The separate second regions 126 also have respective second exposed areas 128 on the front surface 129. The second concentration of dopant in each of the second regions 126 is higher than the first concentration of dopant in the first region 124. The first region 124 may thus be designated as an n type semiconductor material while the second regions 126 may be designated as n+ type semiconductor material, indicating that the second regions have a higher concentration of n-type dopant than the first region. In the embodiment shown, there are four separate second regions 126, but in other embodiments there may be fewer or more second regions 126, each having a corresponding second exposed area 128.

In the embodiment shown in FIG. 6, the semiconductor structure 120 further includes a second doped volume 130 adjacent the first doped volume 122. The second doped volume 130 includes a dopant such as boron, which causes the second doped volume to have a polarity opposite to the polarity of the first doped volume 122. The second doped volume may thus be referred to as p-type material. The first and second doped volumes 122 and 130 thus form a p/n junction 134 therebetween.

In this embodiment the plurality of separate second regions 126 form isotype junctions 127 (shown in broken lines) with the first region 124, and the second regions extend through the first region 124 and partway into the second doped volume 130. Accordingly, in this embodiment the p/n junction 134 between the first and second doped volumes 122 and 130 is non-planar and non-uniform since the p/n junction includes areas 136 adjacent the separate second regions 126 that extend into the second doped volume 130.

### Back Side Connectors

Still referring to FIG. 6, in the embodiment shown, the second doped volume 130 includes a back surface 132, a third region 140, and a plurality of separate fourth regions 142. The third region 140 has a third exposed area 146. The plurality of separate fourth regions 142 each have a fourth concentration of dopant, the dopant being of the same type as that used to dope the third region, e.g. boron. The fourth concentration of dopant in the fourth regions 142 is higher than the third concentration of dopant in the third region 140 and thus the fourth regions 142 may be designated as p+ type semiconductor material while the third region 14 may be designated as p type semiconductor material.

Each of the fourth regions 142 includes a fourth exposed area 144 on the back surface 132. Isotype junctions 282 are formed between the third and fourth regions 140 and 142. The fourth exposed areas 144 may be arranged in patterns similar to those shown in FIGS. 2-5, on the back surface 132 of the semiconductor structure 120, or the fourth exposed areas 144 may extend across the entire back surface 132.

### Ohmic Connections to Semiconductor Structure

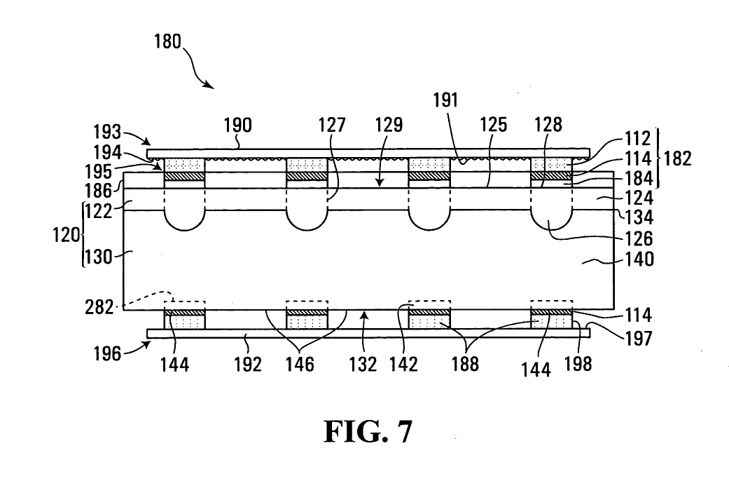

Referring to FIG. 7, a semiconductor apparatus in accordance with an embodiment of the invention is shown generally at 180. The semiconductor apparatus 180 includes the semiconductor structure 120 and further includes a plurality of connection layers 182. The connection layers 182 the alloy 114, and a plurality of first external conductors 112. A dielectric layer 184 may be located between the alloy 114 and the second exposed areas 128 of the first doped volume 122. In this embodiment, the dielectric layer 184 is sufficiently thin to permit tunneling of charge carriers through the dielectric layer between the alloy 114 and the second region 126. The dielectric layer 184 may include silicon dioxide (SiO₂) or silicon nitride (Si₃N₄) and may have a thickness of about 2 nanometers or less.

The first external conductors 112 are bonded to the second exposed areas 128 by the alloy 114 such that each respective first conductor is mechanically and electrically connected to the corresponding second region 126, such that a low resistance, substantially ohmic, connection is formed between the first conductors and respective second regions.

Similarly, a plurality of second external conductors 188 may be bonded by the alloy 114 to the fourth exposed areas 144 on the back surface 132 of the semiconductor structure 120.

The first conductors 112 are previously adhered to a surface 194 of a polymeric film 190. In one embodiment the film 190 comprises polyester and has a thickness of between about 6 microns and 100 microns. The first conductors 1112 are adhered to the film 190 by a layer of adhesive 191 on the surface 194. The adhesive layer 191 may have thickness of between about 20 microns and about 200 microns, for example. The adhesive layer 191 may include an adhesive material having thermoplastic properties, such that the adhesive becomes fluid when subjected to a temperature in the range of between about 60 degrees Celsius and about 170 degrees Celsius, and more particularly between about 80 degrees Celsius and about 150 degrees Celsius.

The first conductors 112 with the alloy 114 coated thereon, are adhered to the film 190 in spaced apart relation prior to being connected to the semiconductor structure to form a unitary first electrode 193 which has a conductor surface portion 195 that protrudes from the adhesive layer 191 coated on the surface 194. The film 190 can thus be manipulated to position the first conductors 112 thereon in alignment with the second exposed areas 128 on the front surface 129, prior to melting and pressing the alloy 114 and making the desired electrical contact between the conductor surface portions 195 and the second exposed areas.

Similarly a unitary second electrode 196 may be prepared in the same way by pre-adhering the second conductors 188 to a film 192 such that the second conductors have a conductor surface portion 198 that protrudes from an adhesive layer coated on a surface 197 of the film 192.

The semiconductor apparatus 180, in the embodiment shown, also includes a first passivation layer 186 deposited on at least the first exposed area 125. The first passivation layer may extend across the entire front surface 129 over both the first exposed area 125 and the second exposed areas 128, for example. The first passivation layer 186 may include a dielectric material such as silicon nitride. The dielectric layer 184 may include silicon nitride or silicon dioxide. The dielectric layer 184 and the first passivation layer 186 may be one and the same or applied separately. The semiconductor apparatus 180 may also include a second passivation layer (not shown) on at least the third exposed area 146 of the back surface 132. Again, the second passivation layer may extend across the entire back surface 132 including the third exposed area 146 and the fourth exposed areas 144.

### Photovoltaic Apparatus & Operation Thereof

The semiconductor apparatus 180 shown in FIG. 7 may be configured to operate as a photovoltaic device. Charge carriers are generated in the semiconductor apparatus in response to receiving light at the front surface 129, and separated at the p/n junction 134. The charge may be collected through the second and fourth exposed areas correspondingly 128 and 144 and used as a source of energy.

When the semiconductor structure 120 is configured to operate as a photovoltaic device, the passivation layer 186 may include an antireflective coating material to minimize reflection of light at the front surface 129, while simultaneously acting as a passivation layer. Advantageously, in photovoltaic devices collection and generation of charge carriers is most efficient in lightly doped areas, which are not shaded by the first conductors 112 due to their positioning over the second exposed areas 128. Light coupling into the first region 124 is enhanced by the antireflective passivation layer 186, which reduces an amount of light reflected from the front surface 129 and increases the amount of light acting on the p/n junction. For example, in embodiments where the first doped volume includes silicon, more than 30% of the incident light may be reflected and unavailable to act on the p/n junction in the absence of an antireflective passivation layer.

Advantageously, the alloy 114 in combination with the higher doping concentrations in the second and fourth regions 126 and 142 facilitate low resistance ohmic contact to the semiconductor structure 120 without substantial voltage drop occurring at the interfaces between the first and second conductors 112 and 188 and the exposed areas 128 and 144 respectively.

### Process-External Conductor Application

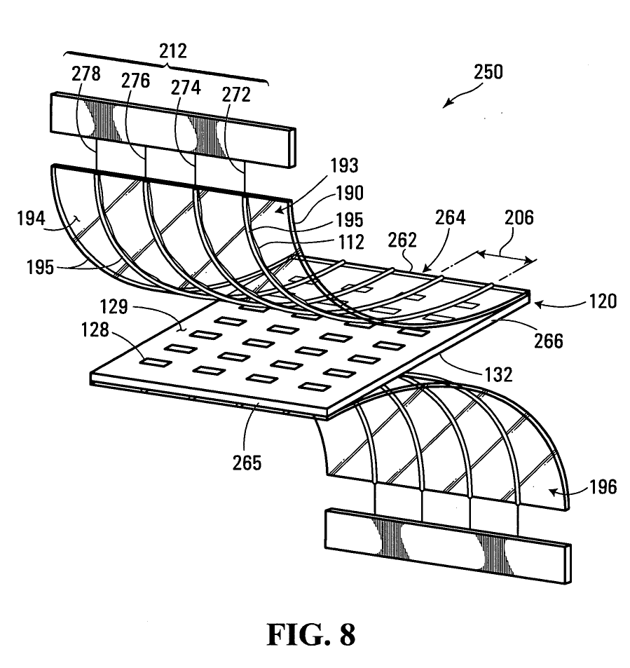

A process for connecting the first conductors 112 and the second conductors 188 to the semiconductor structure 120 (shown in FIG. 2) is shown generally at 250 in FIG. 8.

Referring to FIG. 8 the process starts with cleaning of the second exposed areas 128 and the fourth exposed areas 144 (not shown in FIG. 8) to remove oxides and/or other contaminants therefrom. In one embodiment cleaning may involve etching the second and fourth exposed areas 128 & 144 to expose a clean surface area that is free of oxides.

Initially, the first electrode 193 may be curled as shown in FIG. 8 to align a rear edge 262 of the electrode with a rear edge 264 of the semiconductor structure 120. The first electrode 193 is then pressed downwardly onto the front surface 129 to roll out the film 190 and to secure the surface 194 to the front surface 129 of the semiconductor structure 120, such that the protruding conductor surface portions 195 of the first conductors 112 come into contact with successive second exposed areas 128 between the rear edge 264 and a front edge 265.

The second electrode 196 may be secured to the back surface 132 of the semiconductor structure 120 following a process similar to the process described above for securing the first electrode 193.

When the first and second electrodes 193 and 196 are secured to the semiconductor structure 120, the films 190 and 192 cause the first and second conductors 112 and 188 to be pressed into contact with the second and fourth exposed areas 128 and 144 respectively.

The process continues with heating of the apparatus 180 to cause the alloy 114 to at least partially melt. In some embodiments an external pressure may be applied to the first and second electrodes 193 and 196, to cause the first and second conductors 112 and 188 to be pressed into contact with the second and fourth exposed areas 128 and 144 while heating. After the alloy 114 has at least partially melted, the external pressure is maintained while cooling the apparatus 180 to cause the alloy to bond the first and second conductors 112 and 188 to the second and fourth exposed areas 128 and 144 respectively. At the same time, the adhesive layer 191 begins to melt and flow when heat and pressure are applied, tending to uniformly adhere the film 190 and 192 to the first and third exposed areas 111 and 144.

Advantageously the alloy 114 facilitates good ohmic contact between the first conductors 112 and the second regions 126, and/or the second conductors 188 and the fourth regions 142.

The first conductors 112 are, in this embodiment, laid out in parallel spaced apart relation on the surface 194 of the first electrode 193 with a spacing corresponding to the spacing 206 (shown in FIG. 3) between adjacent columns 200 of the second exposed areas 128 on the front surface 129.

In effect therefore, in this embodiment the second regions 126 and second exposed areas 128 are arranged in rows 160 and columns 200 and the first electrode 193 includes first conductors 112 arranged in parallel spaced apart relation such that when the electrode is applied to the front surface 129 of the semiconductor structure 120, the electrical conductors make contact with the second exposed areas 128 in respective columns.

As shown in FIG. 8, the first electrode 193 may also include a plurality of conductors 272, 274, 276, and 278, which are in contact with the first conductors 112 and extend beyond the film 190 and which are terminated in contact with a common bus 268. The conductors 272, 274, 276, and 278 may be continuous extensions of the first conductors 112.

In an alternative embodiment of the process, the rear edge 262 of the first electrode 193 may be aligned with a right hand side edge 266 of the semiconductor structure 120 and rolled out across the front surface 129 in a manner such that the conductors contact the second exposed areas 128 in respective rows of highly doped areas on the front surface 129 of the semiconductor structure 120.

### Process for Forming First & Second Regions

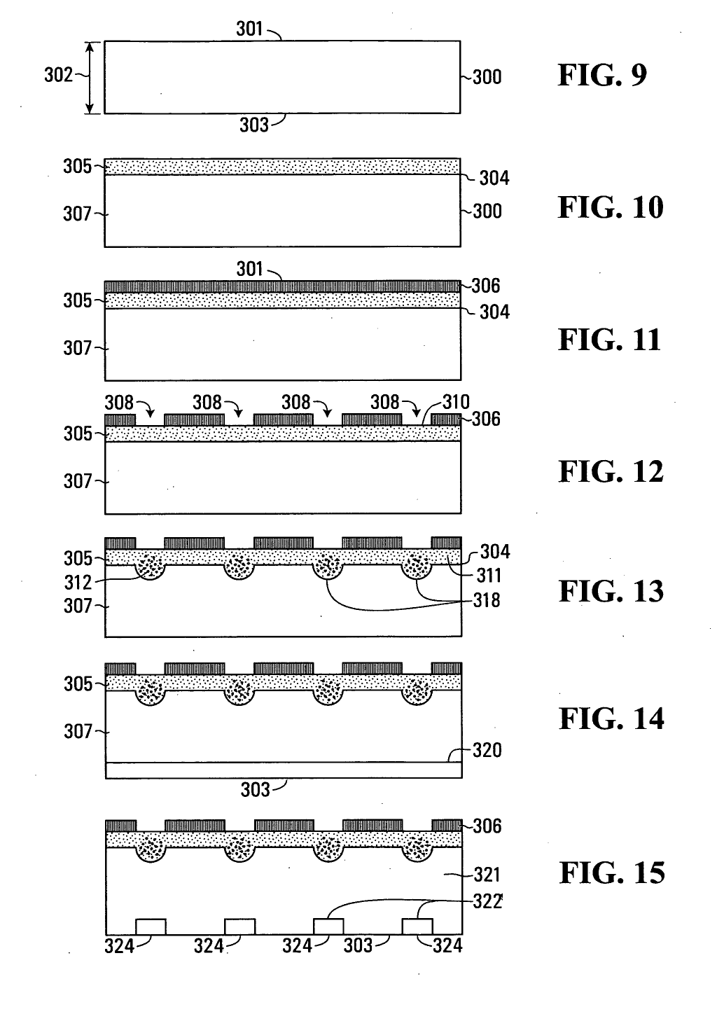

A process for forming the semiconductor structure shown in FIG. 2 for use as a photovoltaic device is shown in FIGS. 9 to 15. Referring to FIG. 9, the process begins with a starting semiconductor material, which in this embodiment includes a p-type crystalline silicon semiconductor wafer 300 having a front surface 301, a back surface 303, and a thickness 302 of about 150 to about 300 microns.

Referring to FIG. 10, the crystalline silicon semiconductor wafer 300 is first doped with a phosphorous, an n-type dopant, to create a p/n junction 304. The p/n junction 304 defines a first doped volume (or emitter region) 305 to one side of the junction 304, and a second doped volume (or collector region) 307 to the other side of the junction 304. After doping, the first doped volume 305 has a majority of n-type polarity dopants, while in the second doped volume p-type dopants remain in majority. The first doped volume 305 may have a sheet resistance of about 80 to 150 ohms per square.

Alternatively, where the crystalline semiconductor wafer 300 includes an n-type semiconductor material, the p/n junction 304 may be formed by doping the semiconductor material with boron to create a p-type emitter region having a sheet resistance of about 80 to 150 ohms per square.

Referring to FIG. 11, the front surface 301 of the semiconductor structure shown in FIG. 10 is then coated with antireflective material 306 such as silicon nitride. The antireflective coating 306 may be deposited using plasma enhanced chemical vapour deposition (PECVD) or other suitable methods. The thickness of the antireflective coating 306 may vary depending upon the desired spectral response of the photovoltaic device and an acceptable light reflection level from the front surface 301.

Referring to FIG. 12, the antireflective coating 306 shown in FIG. 11 is then removed in certain areas to create openings 308 in the antireflective coating. The openings 308 may be formed by selectively laser ablating the antireflective coating 306 or by selective plasma etching, for example. The openings 308 expose areas 310 of the first doped volume 305.

Referring to FIG. 13, the semiconductor wafer 300 is then subjected to a second doping step to locally increase a concentration of phosphorous beneath the exposed areas 310. Doping may be accomplished by thermal diffusion or other conventional methods, and defines first and second regions 311 and 312 in the first doped volume 305, where the dopant concentration in the second region 312 is increased with respect to the dopant concentration in the first region 311. The second region may have a sheet resistance of between about 0.5 to about 40 ohms per square. The second region 312 may also extend into the collector region beyond the original p/n junction 304 to form p/n junction portions 318.

The second doping step may leave residual doping material and derivatives such as oxides on the semiconductor wafer surface and these may be cleaned by etching, for example. By performing the steps shown in FIG. 9 to FIG. 13, effectively a semiconductor wafer having high doped second regions 312 that are not covered by the antireflective coating 306 is produced.

Advantageously the second regions 312 have relatively low resistivity and thus act as relatively good conductors for collecting current within the first doped volume 305. The exposed areas 310 above the second regions 312 facilitate good ohmic contact to the first doped volume 305 for extracting current from the semiconductor wafer 300 and delivering it to external metallic conductors thus functioning as current collecting areas. In general, the exposed areas 310 may occupy about 3-5% of the front surface 301 of the semiconductor wafer 300, thereby only minimally shading the first region 311 where photo-generation of charge carriers occurs most efficiently.

The lower doped first regions are covered by the antireflective coating 306 and are able to absorb light more efficiently than the second regions 312 (particularly in the blue spectral region). However, the first regions 311 have higher resistivity than the second regions 312, and are relatively poor electrical conductors and thus less well suited for current collection.

While most charge generation occurs in the first region 311, some charge generation may also occur in areas of the second region proximate the p/n junction portions 318 where the p/n junction is not shaded by an electrical conductor (as shown in FIG. 7 at 112).

Referring to FIGS. 14 and 15, the process may continue with forming of the second doped volume 307 of the semiconductor wafer 300. The semiconductor wafer 300 produced according to the process described in connection with FIGS. 9 to 13, is further subjected to additional doping by boron, for example, on the back surface 303, to increase the doping concentration underlying the back surface. In the embodiment shown in FIG. 14, substantially the entire back surface 303 is subjected to this additional doping to form an isotype junction 320, which acts as a back side current collecting area for the solar cell apparatus. Again, doping may be achieved using diffusion or other conventional methods as described above in connection with FIG. 9 to FIG. 13.

Referring to FIG. 15, in an alternative embodiment for forming the second doped volume 307, doping may be selectively applied to produce a third region 321 and a plurality of fourth regions 322, where a dopant concentration in the fourth regions is higher than a dopant concentration in he third regions. Each fourth region has a corresponding fourth exposed area 324 which facilitates ohmic connection to the fourth regions 322, as described above. The fourth exposed areas 324 may be distributed across the back surface 303 similar to the distribution of the second areas 128 shown in FIGS. 2-5, thus facilitating contact by the second electrode 196 shown in FIG. 7 and FIG. 8.

While specific embodiments of the invention have been described and illustrated, such embodiments should be considered illustrative of the invention only and not as limiting the invention.

What is claimed is:

1. A semiconductor apparatus comprising:
a first doped volume of semiconductor material, said first doped volume having a front surface and first and second adjacent regions;
said first region having a first concentration of dopant and a first exposed area on said front surface;
said second region having a second concentration of dopant and a second exposed area on said front surface, said second concentration being higher than said first concentration; and
a first external conductor; and
an alloy bonding said first external conductor to said second exposed area to ohmically connect said conductor to said second region.

2. The apparatus of claim 1 wherein said first region has a sheet resistance in the range of between about 80 ohms/sq to about 150 ohms/sq.

3. The apparatus of claim 1 wherein second region has a sheet resistance in the range of between about 0.5 ohms/sq to about 40 ohms/sq.

4. The apparatus of claim 1 wherein said second region comprises a plurality of separate second regions, each of said separate second regions generally having a concentration of dopant approximately equal to said second concentration and each of said separate second regions having a respective second exposed surface.

5. The apparatus of claim 4 wherein said first external conductor is bonded to said second exposed areas of at least two of said plurality of second regions.

6. The apparatus of claim 4 wherein said regions of said plurality of second regions are distributed across said front surface.

7. The apparatus of claim 4 wherein said regions of said plurality of second regions are distributed across said front surface in parallel spaced apart rows.

8. The apparatus of claim 7 wherein said regions in a first parallel spaced apart row are staggered relative to said regions in a second adjacent parallel row.

9. The apparatus of claim 7 wherein said first external conductor comprises a plurality of conductors, each of said plurality of conductors being bonded to a plurality of said second exposed areas of respective said second regions in one of said plurality of parallel rows.

10. The apparatus of claim 1 wherein said first external conductor comprises at least one of silver, copper, and alloys thereof.

11. The apparatus of claim 1 wherein said first external conductor comprises a wire having a diameter of between about 30 microns and about 200 microns.

12. The apparatus of claim 1 wherein said first external conductor comprises at least a portion having a cross sectional shape that is generally circular or generally rectangular or generally triangular.

13. The apparatus of claim 1 wherein a portion of said first external conductor is adhered to a polymeric film and wherein said polymeric film is adhered to said front surface.

14. The apparatus of claim 13 wherein said polymeric film comprises polyester.

15. The apparatus of claim 13 wherein said polymeric film has a thickness of between about 6 microns and about 100 microns.

16. The apparatus of claim 13 further comprising an adhesive between said polymeric film and said front surface, said adhesive being operable to adhere said polymeric film to said front surface.

17. The apparatus of claim 16 wherein said adhesive has thermoplastic properties.

18. The apparatus of claim 16 wherein said adhesive becomes fluid when subjected to a temperature in the range of between about 60 degrees Celsius and about 170 degrees Celsius.

19. The apparatus of claim 16 wherein said adhesive becomes fluid when subjected to a temperature in the range of between about 80 degrees Celsius and about 150 degrees Celsius.

20. The apparatus of claim 16 wherein said adhesive has a thickness of between about 20 microns and about 200 microns.

21. The apparatus of claim 1 wherein said alloy comprises a composition comprising at least two of: Ag, Bi, Cd, Ga, In, Pb, Sb, Sn, and Zn.

22. The apparatus of claim 20 wherein said alloy comprises In, Sn, and Ag in a proportion of about 47% In, about 51% Sn, and about 2% Ag.

23. The apparatus of claim 20 wherein said alloy comprises In and Sn in a proportion of about 48% In and about 52% Sn.

24. The apparatus of claim 1 wherein said alloy has a thickness of between about 1 micron and about 5 microns.

25. The apparatus of claim 1 wherein said alloy has a melting temperature of between about 30 degrees Celsius and about 200 degrees Celsius.

26. The apparatus of claim 1 wherein said alloy has a melting temperature of between about 60 degrees Celsius and about 150 degrees Celsius.

27. The apparatus of claim 1 further comprising a layer of dielectric material between said alloy and said second exposed area, said layer of dielectric material being operable to passivate said second exposed area and being sufficiently thin to permit charge carriers to tunnel through said layer of dielectric material between said second exposed area and said alloy.

28. The apparatus of claim 27 wherein said dielectric material comprises silicon nitride or silicon dioxide.

29. The apparatus of claim 27 wherein said layer of dielectric material has a thickness of less than about 2 nanometers.

30. The apparatus of claim 4 further comprising interconnecting regions extending between at least some of said second regions, said interconnecting regions having a dopant concentration approximately equal to said second dopant concentration, said interconnecting regions being operable to interconnect said second regions within said first doped volume.

31. The apparatus of claim 1 wherein said first doped volume has a first dopant polarity and wherein said apparatus further comprises a second doped volume of semiconductor material adjacent to said first doped volume and having a opposite dopant polarity to said first dopant polarity, said first and second volumes of semiconductor material forming a p/n junction therebetween.

32. The apparatus of claim 31 wherein said p/n junction is operably configured to separate charge carriers in response to irradiation of the apparatus by light.

33. The apparatus of claim 32 further comprising an antireflective layer on said front surface, said antireflective layer having an opening aligned with said second exposed area, said antireflective layer being operably configured to facilitate coupling of said light into said semiconductor apparatus.

34. The apparatus of claim 1 further comprising a passivation layer on said front surface, said passivation layer having an opening aligned with said second exposed area.

35. The apparatus of claim 31 wherein said second doped volume comprises:
a back surface and third and fourth regions;
said third region having a third concentration of dopant and a third exposed area on said back surface;
said fourth region having a fourth concentration of dopant and a fourth exposed area on said back surface, said fourth concentration being higher than said third concentration.

36. The apparatus of claim 35 wherein said third region has a sheet resistance in the range of between about 20 ohms/sq to about 60 ohms/sq.

37. The apparatus of claim 35 wherein fourth region has a sheet resistance in the range of between about 0.1 ohms/sq to about 20 ohms/sq.

38. The apparatus of claim 35 further comprising:
a second external conductor;
an alloy on said second external conductor, said alloy bonding said second conductor to said fourth exposed area to ohmically connect said second conductor to said fourth region.

39. The apparatus of claim 35 wherein said fourth region comprises a plurality of separate fourth regions, each of said separate fourth regions generally having a concentration of dopant approximately equal to said fourth concentration and each of said fourth regions having a corresponding fourth exposed surface.

40. A semiconductor apparatus comprising:
a first doped volume of semiconductor material, said first doped volume having a front surface and first and second adjacent regions;
said first region having a first concentration of dopant and a first exposed area on said front surface;
said second region having a second concentration of dopant and a second exposed area on said front surface, said second concentration being higher than said first concentration; and
a first external conductor; and
first means for bonding said first external conductor to said second exposed area to ohmically connect said first conductor to said second region.

41. The apparatus of claim 40 wherein said first means for bonding comprises an alloy.

42. The apparatus of claim 40 further comprising first means for holding said first external conductor.

43. The apparatus of claim 42 wherein said first means for holding comprises a first polymeric film and a first adhesive securing said first conductor to said first polymeric film.

44. The apparatus of claim 43 wherein said first adhesive is operably configured to secure said first polymeric film to said front surface.

45. The apparatus of claim 40 further comprising means for passivating said second exposed area.

46. The apparatus of claim 45 wherein said means for passivating comprises a layer of dielectric material between said second exposed area and said means for bonding.

47. The apparatus of claim 43 wherein said second regions include a plurality of second regions, each having a respective second exposed surface and wherein said apparatus further comprises means for interconnecting at least some of said second regions together.

48. The apparatus of claim 47 wherein said means for interconnecting comprises means for interconnecting regions having a dopant concentration approximately equal to said second dopant concentration.

49. The apparatus of claim 40 wherein said first doped volume has a first dopant polarity and wherein said apparatus further comprises a second doped volume of semiconductor material adjacent to said first doped volume and having a second dopant polarity opposite to said first dopant polarity, said first and second volumes of semiconductor material forming a p/n junction therebetween.

50. The apparatus of claim 49 wherein said second doped volume comprises:
a back surface and third and fourth regions;
said third region having a third concentration of dopant and a third exposed area on said back surface; and
said fourth region having a fourth concentration of dopant and a fourth exposed area on said back surface, said fourth concentration being higher than said third concentration.

51. The apparatus of claim 50 further comprising:
a second external conductor; and
second means for bonding said second conductor to said fourth exposed area to ohmically connect said second conductor to said fourth region.

52. The apparatus of claim 51 wherein said second means for bonding includes an alloy.

53. The apparatus of claim 51 further comprising second means for holding said second external conductor.

54. The apparatus of claim 53 wherein said second means for holding comprises a second polymeric film and a second adhesive securing said second conductor to said second polymeric film.

55. The apparatus of claim 54 wherein said second adhesive is operably configured to secure said second polymeric film to said back surface.

56. A process for making an electrical connection to a semiconductor structure comprising a first doped volume of semiconductor material, said first doped volume having a front surface and first and second adjacent regions, said first region having a first concentration of dopant and a first exposed area on said front surface, said second region having a second concentration of dopant and a second exposed area on said front surface, said second concentration being higher than said first concentration, the process comprising:
bonding a first external conductor to said second exposed area to ohmically connect said first conductor to said second region.

57. The process of claim 56 wherein bonding comprises melting an alloy between said first external conductor and said second exposed area.

58. The process of claim 56 further comprising holding said first external conductor.

59. The process of claim 58 wherein holding comprises adhesively securing said first conductor to a first polymeric film.

60. The process of claim 59 further comprising securing said first polymeric film to said front surface.

61. The process of claim 56 further comprising passivating said second exposed area.

62. The process of claim 61 wherein passivating comprises forming a layer of dielectric material on said first surface, prior to bonding.

63. The process of claim 59 further comprising interconnecting together at least some of a plurality of separate said second regions.

64. The process of claim 63 wherein interconnecting comprises doping said semiconductor structure to form interconnecting regions between said separate second regions, said interconnecting regions having a dopant concentration approximately equal to said second dopant concentration.

65. The process of claim 56 wherein said first doped volume has a first dopant polarity and wherein said semiconductor structure further comprises a second doped volume of semiconductor material adjacent to said first doped volume and having a opposite dopant polarity to said first dopant polarity, said first and second volumes of semiconductor material forming a p/n junction therebetween, said second doped volume comprising a back surface and third and fourth regions, said third region having a third concentration of dopant and a third exposed area on said back surface, said fourth region having a fourth concentration of dopant and a fourth exposed area on said back surface, said fourth concentration being higher than said third concentration, and wherein said process further comprises bonding a second external conductor to said fourth exposed area to ohmically connect said second conductor to said fourth region.

66. The process of claim 65 wherein bonding said second conductor comprises melting an alloy between said second conductor and said fourth exposed area.

67. The process of claim 65 further comprising holding said second external conductor.

68. The process of claim 67 wherein holding said second external conductor comprises adhesively securing said second external conductor to a second polymeric film.

69. The process of claim 68 further comprising adhesively securing said second polymeric film to said back surface of said semiconductor structure.

70. In a semiconductor structure having a first doped volume of semiconductor material, the first doped volume having a front surface and first and second adjacent regions, the first region having a first concentration of dopant and a first exposed area on the front surface, the second region having a second concentration of dopant and a second exposed area on the front surface, the second concentration being higher than the first concentration, a process for forming electrical connections to the semiconductor structure comprises:
cleaning the second exposed area on the front surface of the semiconductor material;
pressing a first external conductor coated with an alloy into contact with the second exposed area, while heating said alloy to a temperature sufficient to at least partially melt said alloy; and
maintaining said pressing while cooling said alloy to cause said alloy to solidify, thereby bonding said first conductor to said second exposed area such that said first conductor is in ohmic contact with said second region.

71. The process of claim 70 wherein cleaning comprises etching the front surface to remove oxides from the second exposed area.

72. The process of claim 70 wherein pressing comprises pressing to a pressure of between about 0.1 bar and about 1 bar.

73. The process of claim 70 wherein heating comprises heating the structure to cause said alloy to be heated to a temperature of between about 30 degrees Celsius and about 200 degrees Celsius.

74. The process of clam 39 wherein heating comprises heating the structure to cause said alloy to be heated to a temperature of between about 60 degrees Celsius and about 150 degrees Celsius.

75. The process of claim 70 wherein said conductor is adhered to a polymeric film and wherein pressing comprises pressing said conductor into contact with the second exposed area.

76. The process of claim 75 wherein pressing further comprises adhering said polymeric film to the front surface.

77. The process of claim 75 wherein said semiconductor structure comprises an antireflective layer on said first exposed surfaces and wherein pressing further comprises adhering said polymeric film to at least a portion of said antireflective layer.

78. The process of claim 70 further comprising forming a passivation layer on said second exposed area and wherein pressing comprises pressing said first conductor such that said alloy bonds the conductor to said second region through said passivation layer.

79. The process of claim 78 wherein forming said passivation layer comprises forming a layer of dielectric material on said second exposed area.

80. The process of claim 79 wherein forming said layer of dielectric material comprises forming a layer of silicon nitride or silicon dioxide on said second exposed area.

81. The process of claim 80 wherein forming said layer of dielectric material comprises forming a layer of dielectric material such that said layer has a thickness of about 2 nanometers or less.
